(19) United States
(12) Patent Application Publication
(10) Pub. No.: US 2008/0212266 A1
(43) Pub. Date: Sep. 4, 2008

(54) TAMPERPROOFING APPARATUS AND METHODS

(76) Inventor: Dawn White, Ann Arbor, MI (US)

Correspondence Address: GIFFORD, KRASS, SPRINKLE,ANDERSON & CITKOWSKI, P.C, PO BOX 7021, TROY, MI, 48007-7021, US

(21) Appl. No.: 11/972,968

(22) Filed: Jan. 11, 2008

Related U.S. Application Data
(60) Provisional application No. 60/884,506, filed on Jan. 11, 2007.

(51) Int. Cl. H05K 7/00

(52) U.S. Cl. 361/679

(57) ABSTRACT

Anti-tamper enclosures for electronic devices incorporate a variety of passive and active anti-tampering techniques in a novel way, using highly specialized manufacturing techniques that uniquely and innovatively allow such enclosures to be fabricated. Different embodiments include, alone or in combination, enclosures that prevent x-ray and field-ion-beam characterization of the device; detect attempts to mechanically open the enclosure via prying, cutting, machining, etc.; support wireless communication out of the enclosure so that attempts to tamper with the device can be reported to a user; allow insertion of “decoy” devices; and provide a method of destroying the device as a response to a tampering attempt.

### REFERENCE TO RELATED APPLICATION

This application claims priority from U.S. Provisional Patent Application Ser. No. 60/884,506, filed Jan. 11, 2007, the entire content of which is incorporated herein by reference.

### FIELD OF THE INVENTION

This invention relates generally to electronic enclosures and, in particular, to tamper-proof enclosure constructed by consolidating material increments using a process that produces an atomically clean faying surface between the increments without melting the material in bulk.

### BACKGROUND OF THE INVENTION

Increasingly, electronic and other devices embody sensitive military, strategic, or commercial information within their designs, firmware, middleware, and data. Tampering with such devices for the purposes of information theft is an increasing threat to both corporate and national entities. New methods to protect such sensitive devices from destructive, nondestructive, contact, and non-contact tampering techniques are required.

A range of techniques can be used to obtain sensitive design information and data from electronic devices. These include destruction of an enclosure so that data can be copied from storage devices, use of radiography or field ion beam inspection to obtain hardware designs without physical intrusion and other approaches.

Commonly assigned U.S. patent application Ser. No. 09/532,432 now U.S. Pat. No. 6,519,500 and Ser. No. 10/088,040 now U.S. Pat. No. 6,814,823, the entire content of each being incorporated herein by reference, disclose systems and methods for fabricating objects by consolidating material increments in accordance with a description of the object using a process that produces an atomically clean faying surface between the increments without melting the material in bulk. Ultrasonic, electrical resistance, and frictional methodologies, and combinations thereof, may be used for such consolidation.

According to these previous disclosures, the material increments are placed in position to shape the object by a material feeding unit. The raw material may be provided in various forms, including flat sheets, segments of tape, strands of filament or single dots cut from a wire roll. The material may be metallic or plastic, and its composition may vary discontinuously or gradually from one layer to the next, creating a region of functionally gradient material. Plastic or metal matrix composite material feedstocks incorporating reinforcement materials of various compositions and geometries may also be used.

If excess material is applied due to the feedstock geometry employed, such material may be removed after each layer is bonded, or at the end of the process; that is, after sufficient material has been consolidated to realize the final object. A variety of tools may be used for material removal, depending on composition and the target application, including knives, drilling or milling machines, laser cutting beams, grinding, EDM, chemical etch, or ultrasonic cutting tools.

The material increments are fed sequentially and additively according to a computer-model description of the object, which is generated by a computer-aided design (CAD) system, preferably on a layer-by-layer basis. The CAD system, which holds the description of the object, interfaces with a numerical controller, which in turn controls one or more actuators. The actuators impart motion in multiple directions. Three orthogonal directions may be used or five axes, including pitch and yaw as well as XYZ, may be appropriate for certain applications, so that each increment (i.e., layer) of material is accurately placed in position and clamped under pressure.

During these additive manufacturing or free-form fabrication processes, it is often important to provide a support material to the part being produced. This is most often the case when enclosed volumes, or cantilevered sections are being produced, although other types of features with less aggressive unsupported geometries also require the use of supports. There are two types of support structures in free form fabrication, which can be classified as intrinsic and extrinsic.

Intrinsic support structures are those which are essentially produced as a result of the process itself. A classic example of this situation is that pertaining in selective laser sintering or 3D printing, wherein a powder layer is spread across an entire build volume. An operation is performed on certain regions of the powder (i.e., passing a laser over it to melt the powders, or printing binder over it to cause the particles to adhere to each other), which correspond to the cross section of the layer of the part being built to cause the particles to adhere. The remainder of the unaffected powder remains in place as another layer is spread and the process repeated. This mass of unbound powder serves the function of supporting additional layers of material as they are deposited.

Extrinsic support are those in which a second material is used to support the growing structure (examples include shape deposition modeling and inkjet based systems), or in which special support structures are built using the build material or a second material (examples include fused deposition modeling and stereolithography) which are later cut off. In general, intrinsic supports have advantages over the extrinsic types, as they are simpler to implement, since they do not require the supply of a second material.

### SUMMARY OF THE INVENTION

This invention resides in anti-tamper enclosures for electronic devices which incorporate a variety of passive and active anti-tampering techniques in a novel way, using highly specialized manufacturing techniques that uniquely and innovatively allow such enclosures to be fabricated.

Different embodiments include, alone or in combination, enclosures that:
1. prevent x-ray and field-ion-beam characterization of the device;
2. detect attempts to mechanically open the enclosure via prying, cutting, machining, etc.
3. support wireless communication out of the enclosure so that attempts to tamper with the device can be reported to a user;
4. allow insertion of “decoy” devices; and
5. provide a method of destroying the device as a response to a tampering attempt.

### BRIEF DESCRIPTION OF THE DRAWINGS

FIG. 1 shows a basic enclosure in partial cross section constructed in accordance with this invention;

FIG. 2 shows an enclosure in partial cross section constructed in accordance with an alternative embodiment including one or more layers to prevent penetrating ray inspection;

FIG. 3 shows an enclosure in partial cross section constructed in accordance with an alternative embodiment including one or more layers to facilitate external interconnection to an antenna or other device;

FIG. 4 shows an enclosure in partial cross section constructed in accordance with an alternative embodiment including an additional cavity for non-sensitive or decoy devices; and

FIG. 5 shows an enclosure in partial cross section constructed in accordance with the invention including incorporating multiple alternative embodiments.

### DETAILED DESCRIPTION OF THE INVENTION

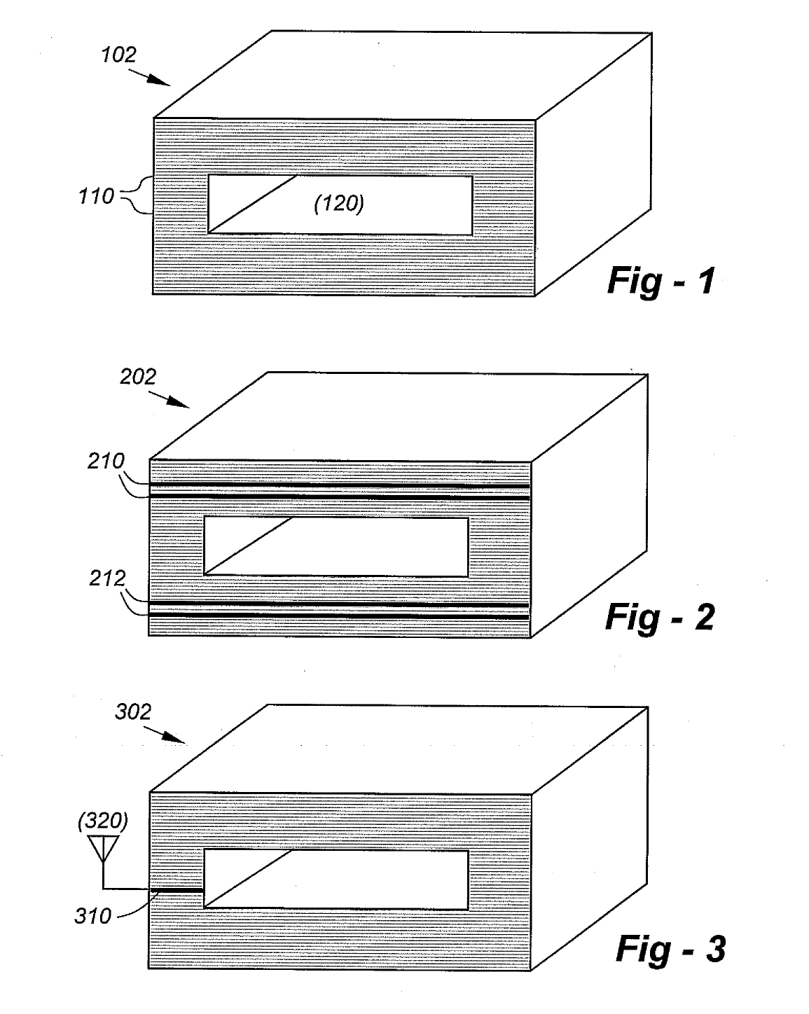

FIG. 1 shows a basic enclosure in partial cross section constructed in accordance with this invention depicted generally at 102. In this and in all embodiments disclosed herein multiple layers 110 are consolidated using processes of the type discussed in the Background, preferably ultrasonic consolidation. It is further assumed that cavity 120 in this and in all embodiments is entirely surrounded on all sides with consolidated material.

FIG. 2 shows an enclosure 202 in partial cross section constructed in accordance with an alternative embodiment including one or more layers 210 to prevent penetrating ray inspection. Certain materials such as lead are opaque to radiation; other materials such as tungsten and aluminum are useful for preventing field-ion-beam analysis. In the embodiment of FIG. 2, one or more such layers are incorporated in the enclosure to prevent inspection. In one implementation, the enclosure in constructed mostly with aluminum, with one or more lead layer consolidated entirely around the cavity to prevent x-ray inspection.

FIG. 3 shows an enclosure in partial cross section constructed in accordance with an alternative embodiment including one or more layers to facilitate external interconnection to an antenna or other device. Although wireless transmission is generally impossible through a sealed metal cavity, an integral antenna lead 310 is built into at least one wall of the enclosure. This allows a variety of wireless transmitters to be enclosed in the solid metal case along with the device to be protected from tampering. Among other applications, when an indication is received that an effort to tamper with the device is occurring, the wireless system can provide an alert to the owner. Symbol 320 is not a physical device and is used only to indicate that the lead 310 may, by itself, act as an antenna. As path 310 is electrically conductive, it may also be used for direct communication to the cavity through physical contact.

Sensors such as accelerometers, thermocouples, radiation sensors, and others can be incorporated in the enclosure, allowing mechanical, thermal, and other events not generally expected to be experienced by the device to be detected. Algorithms may provided to determine, for example, whether an attack on the device by machining of the enclosure has been conducted. Machining creates characteristic chatter on metal surface; this could be enhanced by incorporating a layer of very hard ceramic fibers in the enclosure, and accelerometer or acoustic data may be used to identify such a threat.

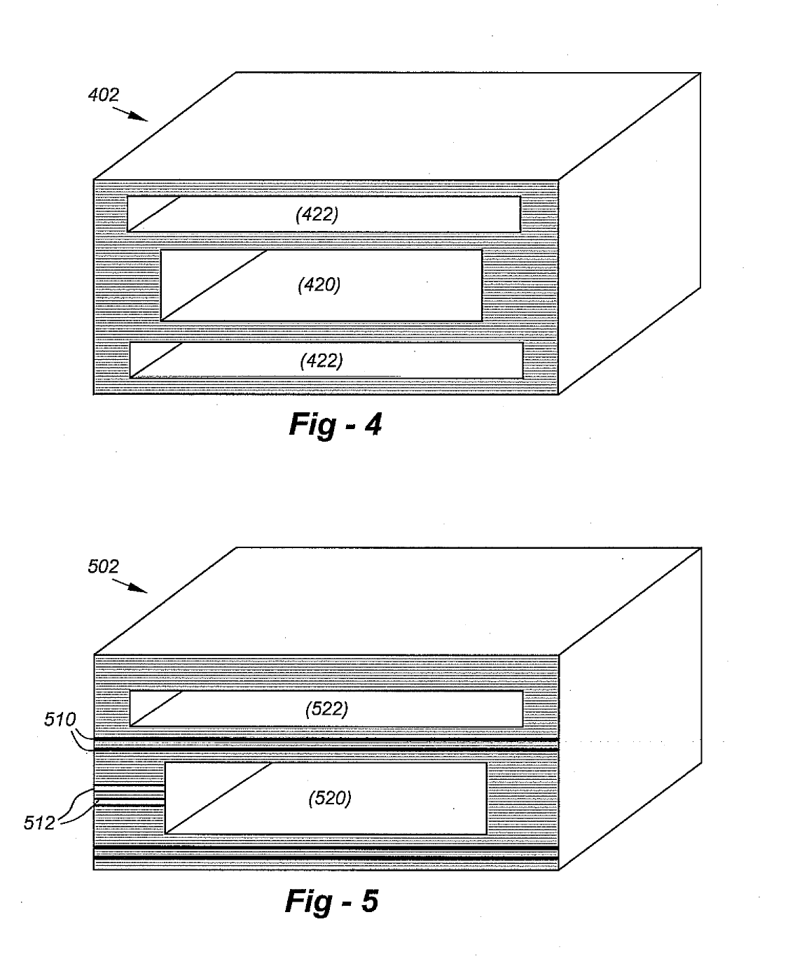

FIG. 4 shows an enclosure in partial cross section constructed in accordance with an alternative embodiment including an additional cavity for non-sensitive or decoy devices. For example, the enclosure may be built with two cavities; one which is shielded from inspection techniques such as radiography and field ion beam, and another which is not. A decoy device of no interest could be enclosed in the unshielded cavity, while the sensitive device was hidden in a region of the enclosure opaque to non-destructive inspection.

With regard to the destruction of device/data, just as an attempt to tamper with a sensitive device can be used to activate a wireless transmitter to alert an owner/attendant, a sensor signal may be used to trigger a device/data destruction technique such as firing of an ultra-capacitor to magnetically or thermally destroy data or a device, release of chemical agent, explosive or other destructive means.

FIG. 5 shows an enclosure in partial cross section constructed in accordance with the invention including incorporating multiple alternative embodiments. Fabrication of a solid metal enclosure embodying all of these features (multiple dissimilar metals, integral antenna, multiple cavities, embedded structural or optical fibers) is impossible using conventional manufacturing technologies such as casting, brazing, welding, etc. In addition, embedded heat sensitive electronic devices within the enclosure using techniques that involve these processes will destroy delicate devices.

Thus, in all disclosed embodiments, solid-state joining technologies are used to circumvent the technical difficulties associated with conventional high temperature processing techniques such as those noted above. In addition, certain very low heat input fusion techniques, employing highly focused heat sources such as laser or electron beam welding may be useful in these applications as well.

In previous patents and invention disclosures we have described the use of ultrasonic, electrical resistance, and friction welding techniques as a means of producing a range of articles having arbitrary geometry, from featureless feedstocks such as wires, sheets, tapes, dots of metal, etc. The contents of these patents and applications are incorporated herein by reference.

In this anti-tampering application, previously shaped layers may be laminated to produce a solid tamperproof enclosure, and featureless layers which are applied and shaped each layer may also be used. For example, for high-volume applications it may be desirable to have previously stamped layers that are applied sequentially to produce an enclosure, incorporate the integral waveguide/antenna portion of the enclosure, and seal off the device. For low-volume devices, it may be desirable to employ featureless feedstocks which are machine via milling, electrical discharge machining, laser cutting, or other such means as suggest themselves, alternately with solid state lamination in order to produce small volumes at lower unit costs.

I claim:

1. A tamperproof enclosure, comprising:
a solid, all metal body constructed by consolidating material increments using a process that produces an atomically clean faying surface between the increments without melting the material in bulk;
a cavity within the body surrounded on all sides by the consolidated material increments; and
electronic circuitry disposed within the cavity.

2. The tamperproof enclosure of claim 1, wherein the body includes one or more layers of lead or other material(s) that interfere with to x-radiation.

3. The tamperproof enclosure of claim 1, wherein the body includes one or more layers of tungsten, aluminum or other material(s) that interfere with field-ion-beam analysis.

4. The tamperproof enclosure of claim 1, wherein the electronic circuitry includes components operative to detect of attempts to gain access to the cavity through prying, cutting, machining, or other techniques.

5. The tamperproof enclosure of claim 1, wherein:
the electronic circuitry includes components operative to detect of attempts to gain access to the cavity through prying, cutting, machining, or other techniques; and
one or more components operative to destroy all or part of the electronic circuitry is an attempt is detected.

6. The tamperproof enclosure of claim 1, wherein the body includes one or more layers facilitating wireless communication out of the enclosure to an external receiver.

7. The tamperproof enclosure of claim 1, wherein:
the electronic circuitry includes components operative to detect of attempts to gain access to the cavity through prying, cutting, machining, or other techniques; and
one or more layers facilitating wireless communication out of the enclosure to an external receiver to report tampering attempts.

8. The tamperproof enclosure of claim 1, further including multiple cavities, at least one of which includes one or more “decoy” devices.

9. The tamperproof enclosure of claim 1, wherein the material increments are consolidated using ultrasonic consolidation.

10. The tamperproof enclosure of claim 1, wherein the material increments are consolidated using ultrasonic consolidation of tapes, sheets, or both.
